(19) United States
(12) Patent Application Publication
(10) Pub. No.: US 2026/0064910 A1
(43) Pub. Date: Mar. 5, 2026

(54) METHOD FOR CONDUCTING A SIL SIMULATION, DEVICE FOR DATA PROCESSING FOR PERFORMING A SIL SIMULATION, COMPUTER PROGRAM PRODUCT, SIGNAL SEQUENCE, AND SIMULATION PLATFORM

(71) Applicant: dSPACE GmbH, Paderborn (DE)

(72) Inventors: Markus SUEVERN, Paderborn (DE); Benedikt MENNE, Paderborn (DE)

(73) Assignee: dSPACE GmbH, Paderborn (DE)

(21) Appl. No.: 19/319,062

(22) Filed: Sep. 4, 2025

(30) Foreign Application Priority Data
Sep. 5, 2024 (EP) 24198570.4

(51) Int. Cl. G06F 30/20

(52) U.S. Cl. CPC G06F 30/20

(57) ABSTRACT

A method for performing a SIL simulation running on a host data processing device and a device for data processing for performing a SIL simulation are provided. The device is configured to execute the method. A computer program product, a signal sequence, and a simulation platform are also provided.

This nonprovisional application claims priority under 35 U.S.C. § 119 (a) to European Patent Application No. 24198570.4, which was filed on Sep. 5, 2024, and which is herein incorporated by reference.

### BACKGROUND OF THE INVENTION

### Field of the Invention

The present invention relates to a method for performing a SIL simulation running on a host data processing device and to a device for data processing for performing a SIL simulation, wherein the device has means configured to execute such a method. The present invention also relates to a computer program product, to a signal sequence, and to a simulation platform.

### Description of the Background Art

In the development of electronic control units, validation of the control unit software running on a target hardware is an integral part of the development process. For example, the behavior of the particular control unit software or parts thereof can be tested in a simulated environment in different development phases by means of “software-in-the-loop” simulations, so-called SIL simulations. For this purpose, the software to be tested can be implemented as a virtual control unit on a suitable simulation platform and the virtual control unit can be simulated within a simulation scenario. In so doing, in addition to certain functions of a target hardware, sensor signals and other simulation participants can also be simulated to the required extent.

For certain test scenarios, however, it may be necessary to simulate the control unit software during a reset event. An example of such a reset event is a call to reset the target hardware of the virtual control unit. However, the target hardware is not present in the SIL simulation and the carrying out of a corresponding reset event cannot be simulated satisfactorily or at all in the context of a SIL simulation using existing hardware models. It is therefore desirable to be able to simulate a virtual control unit in a simple yet reliable manner during a reset event by means of a SIL simulation.

### SUMMARY OF THE INVENTION

It is therefore the object of the present invention to overcome the described disadvantages of the prior art and, in particular, to provide means by which a virtual control unit can be simulated in a simple yet reliable manner during a reset event in the context of a SIL simulation.

The object is achieved by the invention according to a first aspect in that a method is proposed for performing a SIL simulation running on a host data processing device. A virtual control unit is simulated by the simulation within a simulation scenario, wherein the simulation scenario has an occurrence of a reset event, and wherein simulating the reset event involves setting at least one first memory area of at least one memory unit of the host data processing device at least partially to a predefined memory image.

The invention is thus based on the surprising finding that by at least partially separating memory areas of the host data processing device, the contents of certain memory areas associated with the control unit software, to be tested, of the virtual control unit can be selectively changed. As a result, it is surprisingly easily possible to effect a course of the SIL simulation, which at least partially simulates a behavior of a real control unit under the influence of a real reset event, at least in parts, in a realistic manner.

Advantageously, for this purpose, at least the first memory area of the host data processing device, with an association of at least some of the contents stored therein with the control unit software to be tested, is set as the first memory area in advance of the simulation. For example, the first memory area is defined in advance and/or at the start of the simulation. As a result, the memory area is known and can be easily addressed in terms of data technology for setting the predefined memory image. In particular, one or more memory addresses of the first memory area are known, so that the first memory area can be accessed for reading and/or writing. By setting the first memory area to the predefined memory image, the control unit software to be tested can be influenced within the simulation in a way that, as a result, corresponds at least in part to the influence of a real reset event on the control unit software running on a real control unit.

Because setting the first memory area to the predefined memory image represents a measure carried out outside the simulation (of the simulated scenario), it is therefore possible to influence the course of the simulation from outside the simulation by setting the first memory area to the predefined memory image.

In this application, the phrase “ . . . within the simulation . . . ” can be used in particular in connection with “what” is simulated (as opposed to “how/with what means” something is simulated), unless the respective context indicates otherwise. Reference is therefore made to the simulated scenario. The phrase “executed as part of the simulation . . . ” is used in a very similar way in this application.

In this application, the phrase “ . . . outside the simulation . . . ” can be used in particular in connection with “how/with what means” that which is or is to be simulated is simulated, unless the respective context indicates otherwise. Reference is therefore made to the respective measure. Nevertheless, the respective measure can also indirectly influence “what” is simulated.

For example, the predefined memory image can be a snapshot of the first memory area, wherein the snapshot was preferably created at a time before the start and/or at the beginning of the simulation. In particular, all variable values belonging to the control unit software to be tested can be saved using the snapshot before the start of the simulation and/or at the beginning of the simulation. The snapshot can then be used as the predefined memory image.

The predefined memory image can be used, for example, to set one or more variables of the control unit software to be tested to a defined value in accordance with the predefined memory image. In this way, it is particularly easily possible to selectively set the variables of the control unit software to be tested to a defined value (according to the predefined memory image) without at the same time changing or resetting variables of the simulation as such (such as, for instance, a step size or a simulation duration).

It should be particularly emphasized in this context that the reset event even without knowledge of the program code of the virtual control unit, and in particular of the control unit software to be tested, can be advantageously simulated with the proposed method.

In particular, no variables within the program code of the control unit software to be tested need to be known in advance and/or specially defined in order to be able to simulate the reset event. It is therefore not necessary, for example, to examine the program code. This makes the proposed method particularly universally applicable and the simulation is particularly easy for users to carry out and without any detailed knowledge of the program code of the virtual control unit, in particular of the control unit software to be tested. In this respect, knowledge of the first memory area is sufficient without having to know the individual variables assigned the contents of the first memory area.

In addition and above all, the virtual control unit, including the control unit software to be tested, can thus advantageously also be provided at least partially in a binary format, in which case inspection of the program code of the control unit software to be tested is not possible anyway or only under difficult conditions. This significantly increases the flexibility with regard to the possible data formats. Preferably, the virtual control unit for the simulation is therefore provided at least partially in a binary format. For example, to this end, the virtual control unit can be provided at least partially as at least one *.lib file and/or at least one *.obj file.

The proposed method also makes it advantageously possible for the simulation to continue running during the reset event without being stopped. As a result, connections, existing during the simulation, to a simulation environment and/or to experimentation tools can be maintained continuously during the reset event as well.

Preferably, the control unit software to be tested and/or the virtual control unit can be part of the simulation scenario. Advantageously, the virtual control unit is a virtual electronic control unit. For example, the control unit software to be tested can be software that can be executed on an electronic control unit for a motor vehicle. The control unit for which the control unit software to be tested is intended can, for example, be an electronic control unit, in particular for a motor vehicle.

Advantageously, the simulation scenario relates to a scenario from the field of functional safety, particularly in the automotive sector.

It is particularly advantageous in this regard that a control unit software (or parts thereof), including communication between multiple control units, can be tested with virtual control units even before hardware prototypes of the target hardware are available or without these having to be available. In this way, the behavior of the control unit software and, above all, parts of it can be simulated under realistic conditions even during software development and in parallel to or decoupled from hardware development, and any necessary adjustments can be made to the software based on the simulation results. This can speed up the development process.

A simulation platform can preferably be used to perform the SIL simulation. In the platform, for example, both a model of the target hardware (therefore, at least the functionality of the target hardware required for the simulation of the software to be tested) and the control unit software to be tested can then be provided as a virtual control unit, for example, loaded into it. At least some components and/or functions of the target hardware, in particular at least those that interact with the control unit software to be tested according to the simulation scenario, can advantageously be provided for the simulation by the hardware model. As a result, in other words, the model of the target hardware ensures that the control unit software to be tested “sees” the target hardware at its interfaces within the simulation, even though the real target hardware is not even present in the simulation. The provision of such models and advantageous simulation platforms will be addressed in more detail below. All properties of simulation platforms described there can be provided individually and in any combination in the simulation platform used to perform the SIL simulation according to the proposed method.

It is known to the skilled artisan that a real electronic control unit typically has at least one microcontroller and at least one memory unit (in particular at least one main memory, RAM), wherein a software is executed or can be executed on the microcontroller, which software has one or more application programs, one or more operating software, and/or one or more layers for communication with hardware (in particular with the microcontroller). This software can at least partially correspond to the control unit software to be tested using the proposed method as part of the simulation. An “electronic control unit” is often also abbreviated as “ECU”, which stands for “electronic control unit.” A virtual control unit is also abbreviated accordingly as “V-ECU.”

The simulated reset event advantageously represents a reset of a microcontroller. A reset can be understood to mean, for example, a reset of one or more variable values of the respective software, in the present case, therefore, in particular the control unit software to be tested.

The method can advantageously comprise providing the host data processing device on which the SIL simulation is performed.

In the context of this application, a virtual control unit (V-ECU) is understood to mean in particular a combination of the control unit software to be tested, or parts thereof, and an abstraction of a target hardware for the control unit software to be tested. The abstraction of the target hardware (sometimes also referred to as a hardware model) can provide functionalities of the target hardware within the simulation. A virtual control unit advantageously has application and/or basic software parts. For example, the virtual control unit can have an, in particular automatically generated, runtime environment, and/or an operating system. Preferably, the virtual control unit offers functionalities that are comparable to those of real control units.

In the context of this application, a simulation scenario is understood to mean, in particular, a control unit test sequence. The control unit test sequence can, for example, simulate a test drive of a motor vehicle. The control unit software can then be advantageously validated with it. The simulation scenario can also involve exchanging information with other simulation participants and/or with other models, such as an environment model and/or an engine model, in particular receiving data from them and/or sending data to them. For example, simulated sensor data can be provided and/or used in the simulation in this context. Therefore, when the virtual control unit being simulated within a simulation scenario is being discussed, this means, for example, that from the perspective of the virtual control unit, its environment changes according to at least partially predefined rules; for example, the predefined rules can then describe the aforementioned test drive.

Within the context of this application, target hardware is understood to mean in particular hardware, preferably having at least one microcontroller, of an electronic control unit on which control unit software, in particular having at least parts of the control unit software to be tested, can be executed.

Within the context of this application, a memory area can be understood in particular to be a (logically) connected section of a memory unit, for example, a main memory (RAM), of a computer (such as the host data processing device). In particular, the first memory area is, for example, defined or can be defined by at least one memory address, in particular at least one start address and/or at least one end address.

It should also be noted at this point that a reset event in the sense of this application does not mean a restart of the virtual control unit and/or the simulation as such. For such resets (not meant here), one or more simulation participants often have to be reset.

The control unit software to be tested can also be referred to as “software under test,” or “SUT” for short.

In summary, it can be stated that the proposed method can be used to simulate control unit software to be tested, which is intended for execution on electronic control units, during a reset event in a simple but yet efficient and realistic manner within the framework of a SIL simulation. Software functions, virtual control units, or complete networks of virtual control units can be advantageously simulated and thus tested by using the SIL simulation according to the proposed method. A virtual control unit, such as the one used in this simulation, can therefore also be advantageously understood as a simulation model in this context.

Alternatively or in addition, it can also be provided that first information is stored in the first memory area, in particular exclusively, which information preferably represents configuration information of a control unit software to be tested, which is part of the virtual control unit, within the simulation, wherein preferably the first information constitutes variable values of variables of the control unit software to be tested within the simulation.

Thus, by manipulating the first memory area, the first information and thus, for example, configuration information of the control unit software to be tested can be manipulated, in particular at least partially changed. For this purpose, the specific variables of the virtual control unit advantageously do not need to be known.

By means of a predefined first memory area, information of the control unit software to be tested can be separated particularly easily and reliably from other information and thus with regard to its affiliation. In this way, at least the first memory area, in which the contents associated with the control unit software to be tested are stored, can be advantageously reliably identified during the simulation runtime.

By storing only the first information in the first memory area, which, for example, represents configuration information of the control unit software to be tested within the simulation, it is ensured that no data from other simulation components or other applications are changed by setting the first memory area to the predefined memory image. The method can be carried out especially efficiently and reliably as a result.

A change to the first information in the first memory area advantageously leads to a change in the model of the virtual control unit within the simulation.

Configuration information can be understood to mean, for example, the following information: status variables, such as operating times, mileage, and/or control deviations; and/or access rights for querying error memories and/or for adjusting parameters.

Alternatively or in addition, it can also be provided that all configuration information, used within the simulation, and/or all variables of the control unit software to be tested are stored in the first memory area.

As a result, it is possible particularly easily to reliably set the control unit software to be tested to a predefined configuration using the predefined memory image.

Alternatively or in addition, it can also be provided that a reset of a target hardware of the control unit software to be tested, in particular carried out in response to a watchdog event, and/or a software reset for re-reading variable values of variables of the control unit software to be tested are simulated by means of the reset event of the simulation scenario.

In this way, the behavior of the control unit software to be tested can be advantageously checked and validated with regard to so-called functional safety after a reset event (such as a watchdog event or software reset event).

In this regard, a watchdog refers to a function, well known to the skilled artisan, for detecting the failure of a system, such as an electronic control unit in motor vehicles. If, for example, periodic feedback from the system software to the watchdog does not occur or does not occur properly, the watchdog can use this to conclude that the software or another component of the system is malfunctioning and can then initiate suitable measures to address the malfunction. One possible measure can represent a reset of a hardware of the system on which the respective software is running. In this respect, therefore, in the case of electronic control units, a watchdog event can be triggered if there is no feedback from the control unit software of the electronic control unit, whereupon a reset of the electronic control unit is carried out. The virtual control unit (and thus in particular the control unit software to be tested) can be simulated particularly advantageously during such a reset event. using the proposed method.

Similarly, the reset event can simulate the mentioned software reset. A software reset can be provided, for example, after changing parameters in the control unit software to be tested and/or to accelerate successive simulations with different test scenarios.

Advantageously, the reset event can have a hardware reset and/or a software reset.

Alternatively or in addition, it can also be provided that the memory image of the first memory area is created, preferably before the simulation of the reset event and/or before the start of the simulation.

For example, a snapshot of the first memory area can be taken to create the memory image. A redefined memory image is thus available which can be used accordingly in the simulation of the reset event.

In this way, the predefined memory image can be obtained particularly easily and yet reliably with standard values to be used for the reset event for the control unit software to be tested and used for the simulation of the reset event. Above all, it can be advantageously achieved in this way that the predefined memory image contains the correct data for different and/or successive simulations. Because of the proposed method the memory image created can contain precisely the information that is specified for the simulated control unit software to be tested at the start of the simulation.

It can also be provided that the simulation of the reset event involves executing at least one predefined reset function of the control unit software to be tested as part of the simulation.

Freely defined functions can advantageously be executed by the at least one reset function within the simulation after the reset event has occurred. Preferably, the data belonging to the control unit software to be tested are only reset according to the predefined memory image after the reset functions have been executed within the simulation.

The function of the control unit software to be tested can be executed thereby within the simulation (therefore, as part of the simulation), as they can also be used when the control unit software is used on the target hardware, after a reset event has occurred.

Reset functions are therefore understood to be in particular those functions of the control unit software to be tested that are executed as part of the simulation in response to the occurrence of the reset event.

For example, a reset function of the control unit software to be tested can involve accessing a memory area and/or checking of a memory area of the target hardware of the control unit software to be tested within the simulation. The target hardware can be simulated within the simulation using a suitable hardware model of the target hardware (whereby the hardware model simulates, for example, at least the functionality of the memory and/or the necessary interfaces to the control unit software within the simulation).

It can also be provided that, after the reset function has been at least partially executed as part of the simulation, the first memory area is at least partially set to the predefined memory image.

As a result, a time sequence for the aspects to be simulated can be advantageously specified.

Preferably, after the reset function was fully executed as part of the simulation, the first memory area is set to the predefined memory image.

It can also be provided that during the simulation of the reset event there is no interruption of the connection to other simulation participants caused by the simulation of the reset event.

It can be reliably achieved thereby that the simulated reset event takes place as an event within the simulation and therefore as part of the simulation. As a result, the behavior of the corresponding simulation participants in response to the reset event can also be included advantageously and in an especially simple manner. This enables a particularly realistic simulation.

It can also be provided that, in particular within the simulation, the virtual control unit can be at least partially provided by a first software part, which at least partially provides the control unit software to be tested, and a second software part, which at least partially provides a model of at least parts of the target hardware.

A behavior of the control unit software to be tested in relation to a specific target hardware can be simulated very advantageously within the simulation through interaction between the first and second software parts.

Advantageously, the functionality for simulating the reset event, in particular at least partially or completely, is provided by the first and/or second software part. For this reason, simulation platforms without on-board means for simulating a reset event can also be used by the proposed method in a simple way to simulate a reset event. It may indeed then be sufficient that the first and/or second software part can be provided in the simulation platform. Thus, the proposed method can be advantageously executable also with existing simulation platforms.

Preferably, the virtual control unit, which can be loaded and executed in the simulation platform, can be formed totally or in part by the first software part and the second software part.

In particular, it is advantageously possible that an interface that separates the control unit software to be tested from the platform to be executed (be it a real control unit or a virtual control unit) is formed by the second software part within the simulation.

The virtual control unit in this case advantageously comprises the control unit software to be tested and furthermore also all functionalities required for the execution of the control unit software to be tested. A virtual control unit, as can also be used for the present method, can be obtained as follows, for example: First, the control unit software to be tested is translated (i.e., compiled) for a platform on which it is to be executed. Parts of the control unit software to be tested that are not platform-independent are replaced in this case. Control unit software (be it real or virtual control units) can therefore be obtained in particular by combining platform-independent software parts (which correspond to the control unit software to be tested) with platform-specific components. The interface is the same for the platform-specific components for real and virtual control units, but the implementation is different.

For example, the first software part can be integrated into the virtual control unit and thus the control unit software to be tested can be provided and/or executed within the simulation platform and/or for use in the simulation.

For example, the second software part can be integrated into the virtual control unit, and thereby a model of the target hardware or parts thereof can be provided within the simulation platform and/or for use in the simulation, in particular to enable interaction with the control unit software to be tested within the simulation.

In other words, therefore, the target hardware (or parts thereof) can be advantageously simulated within the simulation by the second software part. The control unit software to be tested, also without real hardware having to be available, and the necessary hardware components and/or functionalities can be provided thereby within the simulation at simulation runtime. Alternatively or in addition, sensors also connected to the target hardware can be simulated with the second software part.

For example, the first memory area can be set to the predefined memory image via the second software part. Those scenarios can be advantageously simulated thereby in which the reset event is not triggered, much less controlled, by the control unit software to be tested, and the control unit software to be tested is therefore at least partially limited to reacting to a reset event that has occurred. This corresponds particularly well to certain real-life scenarios.

Preferably, the first and second software parts cooperate within the simulation in such a way that (from the perspective of the control unit software to be tested) at least the hardware components, necessary for the execution of the control unit software to be tested, and/or hardware interfaces are available within the simulation.

Thus, at least just that part of the target hardware can be simulated and made available within the simulation together with the control unit software to be tested that is necessary for the execution of the control unit software to be tested in the simulation. In other words, and expressed figuratively, the hardware components (at least to the extent necessary) can therefore be simulated alongside the control unit software to be tested, such that the control unit software to be tested “thinks” during the simulation that it is being executed on the target hardware. In particular, to this end, the interfaces between the control unit software to be tested and the hardware-dependent part of the control unit software can be simulated.

It can also be provided that the simulation of the reset event involves influencing a course of the simulation by specific effects attributable to the inclusion of the first software part and/or to the inclusion of the second software part, wherein preferably the specific effects attributable to the inclusion of the first software part influence the simulation course at least partially from within the simulation and/or the specific effects attributable to the inclusion of the second software part influence the simulation course at least partially from outside the simulation.

The course of the simulation can be influenced, for example, by the control unit software to be tested (and thus preferably from within the simulation), for instance, by the behavior of the software to be tested in response to the reset event. In this case, the influence can be attributed to specific effects in connection with the first software part (which preferably the control unit software to be tested provides). In other words, the influence can be just a regular behavior of the software to be tested in response to the reset event.

The course of the simulation can be influenced by the simulated hardware, for example, wherein, in particular, the reset event itself is simulated by measures that affect the simulation execution (and are therefore preferably effected from outside the simulation). In this case, the influencing can be attributed to specific effects associated with the second software part (which preferably provides the virtual hardware and/or interfaces to the hardware).

This means that the reset event can in reality be an event “caused” by the target hardware with certain effects on the (real) control unit software running on the respective target hardware. In the context of the simulation, however, the event is caused by bringing about a simulative situation that reproduces the effects of the event.

It can also be provided that the specific effects attributable to the inclusion of the first software part involve providing the predefined reset function of the control unit software to be tested by the first software part, and/or the specific effects attributable to the inclusion of the second software part involve at least partially setting the first memory area to the predefined memory image by the second software part.

By executing the reset function as part of the simulation, the reset function acts from within the simulation. By setting the first memory area outside the simulation to the predefined memory image, this measure, which can lead to a change in the simulated control unit software, acts from outside the simulation.

It can also be provided that the simulation of the reset event involves ending or interrupting the specific effects attributable to the inclusion of the first software part and starting or continuing the specific effects attributable to the inclusion of the second software part.

As a result, the simulation can be performed especially advantageously. The final simulation can, for example, be thought of as being composed of a number of partial simulations. Thus, for example, the reset function of the control unit software to be tested can be executed first by means of corresponding calculations on the host data processing device as part of the simulation, wherein the first memory area has contents existing at this point in time and the simulated virtual control unit (including the control unit software to be tested) can therefore have an initial configuration. This leads to a first part of a simulation. The first memory area is then reset. The simulated virtual control unit (including the control unit software to be tested) can then have a second configuration. Then, a further calculation of the simulation with the correspondingly modified virtual control unit follows. This leads to a second part of a simulation. The final simulation can then be put together from the first and second part (and possibly other parts).

It can also be provided that the control unit software to be tested and the simulated part of the target hardware within the simulation each have at least one interface defined according to AUTOSAR, and the control unit software to be tested and the simulated part of the target hardware are coupled to each other via this interface within the simulation in terms of data technology, wherein, preferably in response to the occurrence of the reset event, a command to perform a reset to the control unit software to be tested is sent from the simulated part of the target via the interface.

This makes it very advantageous to achieve compatibility of the control unit software to be tested with other simulation participants, for example.

It can also be provided that the memory image of the first memory area can be at least partially created by the second software part and/or the first memory area is set at least partially to the predefined memory image by the second software part.

In this way, the second software part can take over at least some of the measures required to simulate the event caused by the target hardware. In a sense, that what “has to do” with the hardware can be provided thereby totally or in part by the second software part.

It can also be provided that the second software part further provides at least one simulation code on which the simulation is based and/or at least one measurement service.

Preferably, the simulation scenario can be at least partially predefined by the simulation code. As a result, it is very easily and reliably possible to specify different simulation scenarios.

For example, the measurement service can provide an interface in accordance with XCP (Universal Measurement and Calibration Protocol).

It can also be provided that the first software part and the second software part can be provided by a common DLL file.

The proposed method thus makes it possible to provide the virtual control unit by means of a DLL file. This makes it particularly easy to compile the virtual control unit for a personal computer and to load it into the respective simulation platform.

DLL is an abbreviation for “Dynamic Link Library” and generally refers to a dynamic program library. In the present case, a DLL file can be generated by a link process. The first software part and the second software part are combined to a certain extent in a common unit in the form of the DLL file.

This makes it possible to simulate a reset event as part of a DLL-based SIL simulation, especially without a functionality, provided by the simulation platform, for simulating a reset event.

In particular, the use of the DLL file (in particular by loading the DLL file into the simulation platform) ensures that the first software part and the second software part use a common memory area (of which the first memory area is at least a part) of the memory unit of the host data processing system. Thus, the second software part can reliably set the first memory area to the predefined memory image. Preferably, the first software part and the second software part are each available as C code or as binary in the form of *.obj or *.lib files.

In this way, the virtual control unit and/or the model of the target hardware can be distributed in a particularly simple yet reliable manner.

For example, the DLL file can be generated by a link process. In this way, the virtual control unit can be provided as a single unit in a simple and reliable manner.

As the functionality for simulating the reset event is provided by the DLL file, simulation platforms without on-board means for simulating a reset event can also be used to simulate a reset event in a simple manner. For this purpose, it must be possible to load the at least one DLL file into the simulation platform. In particular, the virtual control unit need not be provided as a “binary image.”

Advantageously, the at least one DLL file can be used to provide all the necessary means within the simulation platform in order to at least partially simulate the reset event.

For example, the first software part and the second software part can be merged within the DLL file using a link process.

It is advantageous in so doing that the at least one DLL file is not unloaded for and/or during the simulation of the reset event. As a result, any existing connections to other simulation participants can be maintained during the simulation of the reset event.

Preferably, the virtual control unit can be simulated under the reset event in a DLL-based SIL simulation and/or with a standardized simulation platform (for example, according to the FMI standard). This can be particularly realistic and further without having to adapt or expand the respective simulation platform for this.

Alternatively or in addition, it can also be provided that the simulation can be performed on a simulation platform running on the host data processing device, and preferably the performing of the simulation involves loading the DLL file into the simulation platform and/or into a memory unit of the host data processing device, which memory unit has at least the first memory area.

Due to the possibility of loading the DLL file into the simulation platform, the reset event can also be simulated advantageously with conventional simulation platforms without these having to support the simulation of a reset event with on-board resources.

Advantageously, all necessary means can be provided within the simulation platform by means of the DLL files in order to at least partially simulate the reset event.

The simulation platform can be realized, for example, in software, in hardware, or as a combination of both, for example. For example, the simulation platform can be software executable or executed on the host data processing device.

Alternatively or in addition, it can also be provided that the simulation simulates the reset event and/or that the simulation simulates a behavior of the virtual control unit and/or the control unit software to be tested due to the reset event.

The behavior of the control unit software to be tested is, in particular, a behavior at least partially in response to the setting of the first memory area to the predefined memory image.

Alternatively or in addition, it can also be provided that second information, which represents configuration information of the simulation platform and/or state variables of the simulation as such, is stored in a second memory area of the host data processing device, in particular exclusively.

In this way, a separation can be achieved particularly easily between information that defines the virtual control unit (and in particular the control unit software to be tested) within the simulation and information that defines the simulation as such (for example, a simulation time, a simulation step size, etc.). Thus, the control unit software to be tested and ultimately the simulation process can be influenced in a reliable and targeted manner by manipulating the first memory area.

It can also be provided that the target hardware of the control unit software to be tested can be an electronic control unit and/or the target hardware of the control unit software to be tested is different from the host data processing device.

The electronic control unit can, for example, be an electronic control unit for a motor vehicle. The proposed simulation is particularly advantageous especially in the development of electronic control units and above all of those for motor vehicles.

It can also be provided that the host data processing device is a personal computer.

This is particularly advantageous because the simulation can also be carried out thereby with comparatively limited resources.

Instead of a personal computer, however, it is also possible that the host data processing device has or represents a distributed computer system. As a result, for example, the relevant resources can be held ready and made available in a geographically distributed manner. Resources can therefore also be easily expanded as required, for example, to be able to use additional computing power for computationally intensive simulations.

The object is achieved by the invention according to a second aspect in that a device for data processing for performing a SIL simulation is proposed, the device having means configured to execute a method according to the first aspect of the invention.

All the advantages described in relation to the method according to the first aspect of the invention also apply accordingly to the device according to the second aspect of the invention. Therefore, reference can be made in this respect to the previous statements.

The features described in relation to the method according to the first aspect of the invention can also be provided in the device accordingly, individually and in any combination, unless the context indicates otherwise.

The device for data processing preferably has at least one processor and/or at least one memory unit in which the first memory area and/or second memory area described in relation to the first aspect of the invention is or are provided.

For example, the device for data processing can have or represent the host data processing device described in relation to the first aspect of the invention.

The object is achieved by the invention according to a third aspect in that a computer program product is proposed which comprises instructions which, when the program is executed by a device for data processing, in particular the device for data processing according to the second aspect of the invention, cause it to execute a method according to the first aspect of the invention.

The object is achieved by the invention according to a fourth aspect in that a signal sequence is proposed, which can be transmitted in particular via a computer network, wherein the signal sequence represents data of at least one DLL file, which DLL file is usable in a method according to the first aspect of the invention.

All necessary means to simulate the reset event, at least in part, can be exchanged advantageously between different participants by the signal sequence.

For example, the signal sequence can be received by a remote computer.

The object is achieved by the invention according to a fifth aspect in that a simulation platform is proposed which is configured to load at least one DLL file which is either described in connection with the first aspect of the invention and/or can be transmitted by a signal sequence according to the fourth aspect of the invention.

In this way, a simulation platform can be used particularly advantageously to simulate a virtual control unit under a reset event.

For example, the simulation platform can be a PC-based simulation platform that supports SIL tests in the development of electronic control units. To this end, the simulation platform can advantageously enable the simulation of a large number of different models, including functional models, functional mock-up units (FMUs), virtual control units, and vehicle models, as well as networks of virtual control units and bus systems, independent of any simulation hardware, especially also in the early phases of development, and preferably be set up accordingly. In scenarios with multiple models, the simulation platform can advantageously enable the import, linking, and execution of (in particular any number of) functional and route models based on modeling software and/or functional mock-up interface (FMI) and preferably be set up accordingly.

Advantageously, the simulation platform can be standardized according to the FMI standard.

All the advantages and features described in relation to the method according to the first aspect of the invention also apply accordingly to the computer program product according to the third aspect of the invention, to the signal sequence according to the fourth aspect of the invention, and to the simulation platform according to the fifth aspect of the invention, unless otherwise apparent from the context in each case. Therefore, reference can be made in this respect to the previous statements.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic representation of a device for data processing according to the second aspect of the invention;

FIG. 2 shows a schematic representation of a memory unit of the device for data processing of FIG. 1;

FIG. 3 shows a block diagram of a simulation platform according to the fifth aspect of the invention; and

FIG. 4 shows a flow chart of a method according to the first aspect of the invention.

### DETAILED DESCRIPTION

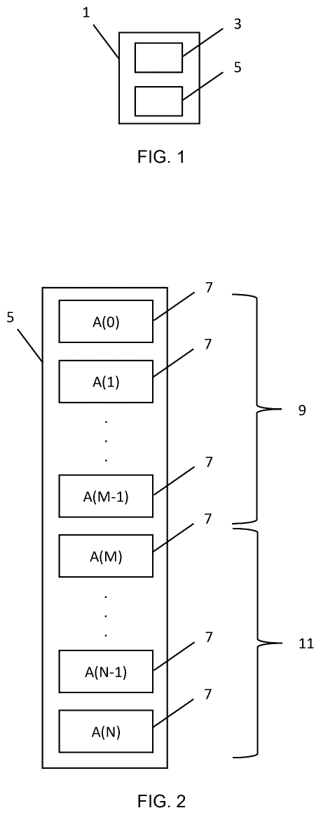

FIG. 1 shows a schematic representation of a device for data processing 1 according to the second aspect of the invention.

The device for data processing 1 has a processor 3 (for example, an X86 processor) and a memory unit 5. The device for data processing 1 can also have other components, such as input units, output units, interfaces, etc. Preferably, the device for data processing 1 is a personal computer.

FIG. 2 shows a schematic representation of memory unit 5.

Memory unit 5 has a large number of N memory cells 7. Each memory cell 7 can be addressed via a memory address A( . . . ) in order to read the contents of the respective memory cell 7 and/or to write a content to the respective memory cell 7. Memory unit 5 can be a RAM memory (main memory) of the device for data processing device 1. For example, the M memory cells 7 with the addresses A(0) to A(M−1) represent a first memory area 9 of memory unit 5 and/or the N−M+1 memory cells 7 with the addresses A(M) to A(N) represent a second memory area 11 of memory unit 5. In other examples, memory unit 5 can have further memory cells that are not necessarily associated with first memory area 9 and second memory area 11. In still other examples, memory unit 5 can be made up of multiple sub-memory units, which can also be spatially distributed.

The device for data processing 1 can be used to perform a SIL simulation of software that is to be executed on an electronic control unit (ECU). This software is therefore control unit software and is referred to as the control unit software to be tested in the context of the simulation. In this case, the control unit software to be tested can include the complete software as it is to be executed later on the electronic control unit. However, the control unit software to be tested can also be formed of only part of the complete software. In this way, individual parts of the software can also be simulated individually and at different development stages. This makes it possible that individual software parts can be developed and tested in parallel and that the individual parts are brought together only at a later date. A further advantage of the SIL simulation is that the tests can be carried out independently of the target hardware. The target hardware is the hardware on which the control unit software to be tested is to be executed later. The target hardware can have or represent a microcontroller. Due to the aforementioned independence, software development can also take place in parallel with hardware development. SIL simulations therefore offer an efficient option of continuously validating software for electronic control units during their development process.

Software running on a (real) electronic control unit interacts with the respective hardware of the electronic control unit in a variety of ways. For example, the software can send and/or receive data via physical interfaces of the electronic control unit. The electronic control unit can be connected, for instance, to one or more bus systems via these interfaces and exchange data with other bus participants via them. The other bus participants can be sensors, for example, that capture data from the surrounding area (in the case of an electronic control unit for motor vehicles, this can be, for example, a vehicle speed, an engine temperature, an engine torque, etc.) and provide these to the electronic control unit. The electronic control unit can then use these data in the control and/or regulation of a control and/or regulating variable. The hardware of the electronic control unit can also be directly coupled to other systems using data technology and, for example, send a regulation and/or control signal to them. An example of an electronic control unit in the vehicle sector is an electronic control unit for a motor vehicle engine, which is then also referred to as an engine control unit.

Because the target hardware is not present on the device for data processing 1 during the SIL simulation, the functions provided by the target hardware in productive use are also simulated, at least to the extent that they are required during the simulation for the control unit software to be tested. For this purpose, a hardware model can be used that provides the necessary functions for the simulation (for example, the receiving of sensor data). The model can therefore be understood as an abstraction of the target hardware, which provides the hardware functionality required for the simulation of the software to be tested in the simulation. Moreover, the control unit software to be tested is also provided in the simulation. Both together, the hardware abstraction and the control unit software to be tested, form the virtual control unit used for the simulation. In other words, the virtual control unit can therefore be understood as the control unit software to be tested together with everything that is required for the execution of the control unit software to be tested. It is desirable that the virtual control unit can be simulated with such a SIL simulation under the influence of a reset event as well. For example, the reset event can be a reset of a microcontroller that the target hardware has or that the target hardware is formed of.

A simulation platform can be used to perform a corresponding SIL simulation on the device for data processing 1 acting as a host data processing device.

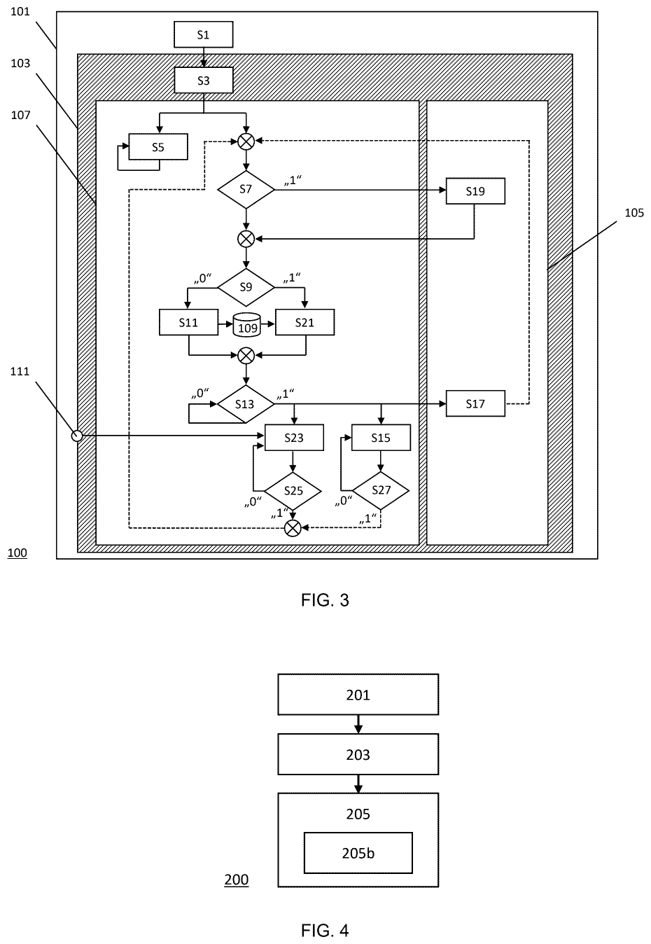

FIG. 3 shows a block diagram 100 of a simulation platform 101 according to the fifth aspect of the invention. In the decision blocks of block diagram 100, from which a number of options (paths) are alternatively possible, the path that is followed with a positive result (“Yes”) is marked with “1” and the path that is followed with a negative result (“No”) is marked with “0.”

Simulation platform 101 provides a simulation environment on the device for data processing 1. A DLL file 103 can be loaded into this. The DLL file can, for example, have been received by means of a signal sequence according to the fourth aspect of the invention, for instance, from a data carrier and/or via a computer network. For better orientation, block 103 of the DLL file is shown hatched in block diagram 100. The loaded DLL file 103 provides a first software part 105 and a second software part 107 in simulation platform 101, and specifically within the simulation environment. With first software part 105, the control unit software to be tested is made available within simulation platform 101 and thus within the simulation environment. With second software part 107, a model of the respective target hardware is made available within simulation platform 101 and thus within the simulation environment. Both software parts 105 and 107 make the virtual control unit available within simulation platform 101 and thus within the simulation environment. The DLL file can be generated beforehand, for example, by means of a link process, from the two (in particular initially individually present) software parts 105, 107 and thus combine both software parts 105, 107 in the DLL file.

The DLL file is loaded into the simulation platform in a block S1. For this purpose, DLL file 103 can, for example, be loaded into a memory of the device for data processing 1.

The variables of the SIL simulation are then initialized in a block S3. In this case, for example, all global variables of the simulation can be initialized by a startup code of a compiler of simulation platform 101. The initialization of the variables of the control unit software to be tested and the model of the target hardware, therefore, those of the first and second software parts 105 and 107, can also be carried out in addition. For example, the variables of the control unit software to be tested can be stored in first memory area 9. As a result, all configuration information of the control unit software to be tested is preferably stored in first memory area 9. For example, the variables of simulation platform 101 can be stored in second memory area 11. As a result, all configuration information of the simulation platform (including any simulation parameters, such as their step size, simulation duration, etc.) is preferably stored in second memory area 11.

Subsequently, various services and/or functions of the target hardware can be executed in a block S5 mediated by second software part 107. Examples of this are measurement services (such as XCP) and the like. It is also checked in an S7 block whether a reset was requested. If this is not the case, in particular after a start of simulation platform 101, it is checked in a block S9 whether there is a memory image of first memory area 9 of the device for data processing 1 (therefore, the host data processing device). If such a memory image does not exist, in particular after a restart or initial start of simulation platform 101, a memory image 109 of first memory area 9 of memory unit 5 is created in a block S11 and temporarily stored in a memory of the device for data processing 1 (for example, in a memory area other than the first and second memory areas 9, 11 of memory unit 5). The configuration information of the control unit software to be tested is therefore saved in memory image 109 at a specific point in time after the first initialization, in particular immediately after the first initialization. The start of the simulation is then waited for in a block S13.

When the SIL simulation is started, the target hardware is emulated in a block S15 to the extent necessary for simulating the control unit software to be tested. For example, functionalities typically provided by the target hardware are made available in the simulation in this way. In addition, when the SIL simulation is started, functions of the control unit software to be tested are executed in a block S17. In the overall view, the virtual control unit is therefore simulated thereby. This is done according to a manner predetermined by a simulation scenario. For example, the simulation scenario can represent a journey with a motor vehicle through a city center. For this purpose, all input variables (such as sensor data, etc.) required for testing the control unit software can be provided virtually to the control unit software to be tested. In other words, for the control unit software to be tested, this “appears” within the simulation as if the vehicle were driving through the city center.

A reset event can also be part of the simulation scenario. For example, a software reset can be performed on a real control unit to re-read the variable values of the control unit software variables. If such a reset event (this can also be referred to as a “software reset”) is to be simulated as part of the simulation scenario, the simulation leaves block S17 and returns to block S7. For example, to this end, the control unit software to be tested can address an interface formed by the simulated target hardware within the simulation, whereupon the further course of the reset event takes place, which is then handled in a simulation-specific manner compared to a real control unit. This is illustrated in block diagram 100 by a dashed arrow leading away from block S17. Block S7 therefore defines a return marker, so to speak, to which the system jumps when the reset event occurs according to the simulation scenario. Because a reset has now been requested, one or more reset functions of the control unit software to be tested are then executed in block S19. In the case of real control units, for example, this can be a check of a memory area of the hardware memory. After the reset functions have been executed, it is checked in block S9 whether there is a memory image of first memory area 9 of the device for data processing 1. If such a memory image exists, in particular as after the start of the simulation, first memory area 9 is set in a block S21 to memory image 109, stored in the memory and therefore predefined. The contents of first memory area 9 that have changed since the backup was performed are overwritten thereby. In this way, the configuration information of the control unit software to be tested is therefore set after the first initialization to the values existing at the time of the backup in block S11. In particular, the values of simulation platform 101 are not changed as a result, however, because these are located in second memory area 11. Subsequently, the start of continuation of the SIL simulation is waited for in block S13 and then functionalities of the target hardware are again simulated in block S15 and the functions of the control unit software to be tested are executed in block S17.

Because the simulation of the virtual control unit is thus continued with the values according to the restored memory image 109, the measure of restoring memory image 109 to the first memory area 9 within the simulation, carried out by second software part 107 from outside the simulation, acts as if a reset had been carried out on the control unit software to be tested.

It is evident from block diagram 100 how the reset event and the subsequent behavior of the control unit software to be tested are simulated within the simulation by an interplay between first software part 105 and second software part 107. In other words, both software parts 105 and 107 therefore contribute to the simulation of the reset event. In this regard, by including first software part 105, the course of the simulation is influenced from within the simulation (in particular by the executed reset functions in block S19) and by including second software part 107, the course of the simulation is influenced from outside the simulation (in particular by resetting the first memory area 9 in block S21).

Alternatively or in addition, part of the simulation scenario can also be a reset event that is triggered externally. In real control units, an externally triggered reset event can occur, for example, when a control unit is monitored by another control unit. If the monitoring additional control unit detects a malfunction in the control unit to be monitored, the monitoring additional control unit can reset the monitored control unit using an external reset signal. This is a case of a reset event, also known as a hardware reset. To simulate such a reset event, in examples, a detection of an external reset request is started in a block S23 after the start of the simulation. A reset signal can be read in via a VPU port 111. If a request for an external reset is detected in block S25 and therefore such a reset event is to be simulated as part of the simulation scenario, the simulation returns to block S7. This is illustrated in block diagram 100 by a dashed arrow leading away from block S25 (or the subsequent node). In this case as well, block S7 thus is again a return marker, so to speak, to which the system jumps when the reset event occurs according to the simulation scenario. The further steps in the simulation of the reset event are very similar to those described above, so that reference can be made to the previous explanations.

Alternatively or in addition, part of the simulation scenario can also be a reset event that has a hardware reset triggered by the simulated hardware functionality (therefore, the emulation of parts of the target hardware in the form of microcontroller hardware). For example, such a reset can be triggered in real control units by a so-called watchdog hardware if the control unit software of the control unit does not reset the “watchdog” at regular intervals due to a malfunction. To this end, in examples, such a hardware reset can be detected in a block S27 within the context of the simulation and simulated as part of the simulation scenario. If the hardware of the electronic control unit is to be reset in response to a watchdog event, this can be simulated in that the simulation is returned to block S7 after such a reset event is detected. The further steps in the simulation of the reset event are here also again very similar to those described above, so that reference can be made to the previous explanations.

Block diagram 100 thus advantageously illustrates a reset event of a DLL-based SIL simulation of a virtual control unit. As a result, a virtual control unit (and in particular the control unit software to be tested) can be realistically simulated under a reset event in a DLL-based SIL simulation without simulation platform 101 having to be adapted or expanded.

FIG. 4 shows a flow chart of a method 200 according to the first aspect of the invention.

In 201, a host data processing device is provided with a simulation platform available on it for performing a SIL simulation of a virtual control unit. The simulation platform can be designed like simulation platform 101 described with reference to the block diagram in FIG. 3.

In 203, a control unit software to be tested and a model of a target hardware of the control unit software to be tested are provided in the simulation platform. This is done, for example, by loading a DLL file into the simulation platform. The control unit software to be tested and the model of the target hardware together represent the virtual control unit.

In 205, the virtual control unit is simulated within a simulation scenario with the simulation platform. In this regard, the simulation scenario shows the occurrence of a reset event. To simulate the reset event, in 205b at least a first memory area of a memory unit of the host data processing device is at least partially set to a predefined memory image.

The features disclosed in the foregoing description, in the drawings, and in the claims can be essential to the invention in its various examples, both individually and in any combination.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for performing a SIL simulation running on a host data processing device, the method comprising:
simulating a virtual control unit by the simulation within a simulation scenario;
providing the simulation scenario with an occurrence of a reset event; and
simulating the reset event by setting at least one first memory area of at least one memory unit of the host data processing device at least partially to a predefined memory image.

2. The method according to claim 1, wherein first information is stored in the first memory area exclusively, which information represents configuration information of a control unit software to be tested, which is part of the virtual control unit, within the simulation, and wherein the first information constitutes variable values of variables of the control unit software to be tested within the simulation.

3. The method according to claim 1, wherein, carried out in response to a watchdog event, a reset of a target hardware of the control unit software to be tested, and/or a software reset for re-reading variable values of variables of the control unit software to be tested are simulated by the reset event of the simulation scenario.

4. The method according to claim 1, wherein the simulation of the reset event involves executing at least one predefined reset function of the control unit software to be tested as part of the simulation, and wherein, after the reset function has been at least partially executed as part of the simulation, the first memory area is at least partially set to the predefined memory image.

5. The method according to claim 1, wherein during the simulation of the reset event there is no interruption of the connection to other simulation participants caused by the simulation of the reset event.

6. The method according to claim 1, wherein, within the simulation, the virtual control unit is at least partially provided by a first software part, which at least partially provides the control unit software to be tested, and a second software part, which at least partially provides a model of at least parts of the target hardware, wherein:
(i) the simulation of the reset event involves influencing a course of the simulation by specific effects attributable to the inclusion of the first software part and/or to the inclusion of the second software part,
wherein the specific effects attributable to the inclusion of the first software part influence the simulation course at least partially from within the simulation and/or the specific effects attributable to the inclusion of the second software part influence the simulation course at least partially from outside the simulation,
(ii) the specific effects attributable to the inclusion of the first software part involve providing the predefined reset function of the control unit software to be tested by the first software part, and/or the specific effects attributable to the inclusion of the second software part involve at least partially setting the first memory area to the predefined memory image by the second software part, and/or
(iii) the simulation of the reset event involves ending or interrupting the specific effects attributable to the inclusion of the first software part and starting or continuing the specific effects attributable to the inclusion of the second software parts.

7. The method according to claim 6, wherein the first software part and the second software part are provided by a common DLL file.

8. The method according to claim 1, wherein the simulation is performed on a simulation platform running on the host data processing device, and wherein the performing of the simulation involves loading the DLL file into the simulation platform and/or into a memory unit of the host data processing device, which memory unit has at least the first memory area.

9. The method according to claim 1, wherein the simulation simulates the reset event and/or the simulation simulates a behavior of the virtual control unit and/or the control unit software to be tested due to the reset event.

10. A device for data processing for performing a SIL simulation, the device being configured to execute the method according to claim 1.

11. A computer program product comprising instructions which, when the program is executed by a device for data processing causes the device to execute the method according to claim 1.

12. A signal sequence adapted to be transmitted via a computer network, wherein the signal sequence represents data of at least one DLL file, which DLL file is used in the method according to claim 1.

13. A simulation platform configured to load at least one DLL file according to claim 7.
